(19) United States
(12) Patent Application Publication
(10) Pub. No.: US 2025/0006722 A1
(43) Pub. Date: Jan. 2, 2025

(54) INTEGRATED CIRCUIT LOW CAPACITANCE ELECTROSTATIC DISCHARGE DIODES

(71) Applicant: Advanced Micro Devices, Inc., Santa Clara, CA (US)

(72) Inventors: Ravi Kumar KALLEMPUDI, Bengaluru (IN); Robert Scott RUTH, Fort Collins, CO (US); Suhas SHIVARAM, Bengaluru (IN)

(73) Assignee: Advanced Micro Devices, Inc., Santa Clara, CA (US)

(21) Appl. No.: 18/215,675

(22) Filed: Jun. 28, 2023

(51) Int. Cl. H01L 27/02; H01L 21/8228; H02H 9/04

(52) U.S. Cl. CPC H01L 27/0255; H01L 21/8228; H01L 27/0292; H02H 9/046

(57) ABSTRACT

A semiconductor electrostatic discharge (ESD) protection circuit comprises an N diode for limiting negative going voltages with reference to ground (V_{SS}) and a P diode for limiting positive going voltages with reference to a positive supply voltage (V_{DD}). The N-diode is formed in a single P-well surrounded by an N-well ring. The P-diode is formed in a single N-well surrounded by a P-well ring. The N-diode comprises a plurality of N+ fingers, each N+ finger is surrounded by a P+ guard ring. The P-diode comprises a plurality of P+ fingers, each P+ finger surrounded by an N+ guard ring. The plurality of N+ fingers and P+ fingers are coupled to an input-output pad. The P+ guard rings are coupled to ground (V_{SS}) and the N+ guard rings are coupled to the positive supply voltage (V_{DD}).

### TECHNICAL FIELD

Embodiments of the present disclosure generally relate to integrated circuit electrostatic discharge protection, and in particular, to low capacitance electrostatic discharge protection diodes for signal inputs and outputs.

### BACKGROUND

Electrostatic discharge (ESD) is a sudden and momentary flow of electric current between two electrically charged objects caused by contact, an electrical short or dielectric breakdown. A buildup of static electricity can be caused by tribocharging or by electrostatic induction. The ESD occurs when differently-charged objects are brought close together or when the dielectric between them breaks down.

One of the causes of ESD events is static electricity. Static electricity is often generated through tribocharging, the separation of electric charges that occurs when two materials are brought into contact and then separated. Examples of tribocharging include walking on a rug, rubbing a plastic comb against dry hair, rubbing a balloon against a sweater, ascending from a fabric car seat, or removing some types of plastic packaging. In all these cases, the breaking of contact between two materials results in tribocharging, thus creating a difference of electrical potential that can lead to an ESD event.

Another cause of ESD damage is through electrostatic induction. This occurs when an electrically charged object is placed near a conductive object isolated from the ground. The presence of the charged object creates an electrostatic field that causes electrical charges on the surface of the other object to redistribute. Even though the net electrostatic charge of the object has not changed, it now has regions of excess positive and negative charges. An ESD event may occur when the object comes into contact with a conductive path. For example, charged regions on the surfaces of Styrofoam™ cups or bags can induce potential on nearby ESD sensitive components via electrostatic induction and an ESD event may occur if the component is touched with a metallic tool.

Many electronic components, especially integrated circuits and microchips, can be damaged by ESD. Sensitive components need to be protected during and after manufacture, during shipping and device assembly, and in the finished device. Manufacturers and users of integrated circuits must take precautions to avoid ESD. ESD prevention can be part of the device itself and include special circuit design techniques for integrated circuit device input and output pins. ESD protection circuits provide energy dissipation paths between any combinations of two pins of the integrated circuit to limit the voltage potential there between.

### SUMMARY

In one example of the disclosure, an apparatus for protection of integrated circuit inputs and outputs from electrostatic discharge (ESD) includes an integrated circuit (IC) substrate, a P-well in the IC substrate, an N-well in the IC substrate, an N-well ring around the P-well and in the IC substrate, a P-well ring around the N-well and in the IC substrate. At least two fingers of an N-diode comprising N+ implants in the P-well. At least two guard rings comprising P+ implants in the P-well, wherein each guard ring surrounds an associated finger of the N-diode. At least two fingers of a P-diode comprising P+ implants in the N-well. At least two guard rings comprising N+ implants in the N-well, wherein each guard ring surrounds an associated finger of the P-diode.

In one example of the disclosure, an integrated circuit (IC) having electrostatic discharge (ESD) protection for signal inputs and signal outputs of the IC includes an integrated circuit (IC) substrate having electronic circuits with signal inputs and outputs, and at least one ESD protection circuit for each signal input and each signal output of the electronic circuits. Each one of the at least one ESD protection circuits includes a P-well in the IC substrate, an N-well in the IC substrate, an N-well ring around the P-well and in the IC substrate, a P-well ring around the N-well and in the IC substrate. At least two fingers of an N-diode include N+ implants in the P-well. At least two guard rings include P+ implants in the P-well, wherein each guard ring surrounds an associated finger of the N-diode. At least two fingers of a P-diode include P+ implants in the N-well. At least two guard rings include N+ implants in the N-well, wherein each guard ring surrounds an associated finger of the P-diode.

In one example of the disclosure, a method for providing electrostatic discharge (ESD) protection for signal inputs and signal outputs of an integrated circuit (IC) includes providing at least one ESD protection circuit for each signal input and each signal output of circuits in an IC substrate. Each one of the at least one ESD protection circuits includes providing a P-well in the IC substrate. Providing an N-well in the IC substrate. Surrounding the P-well with an N-well ring in the IC substrate and surrounding the N-well with a P-well ring in the IC substrate. Providing at least two fingers of an N-diode comprising N+ implants in the P-well. Surrounding each of the at least two fingers of the N-diode with an associated guard ring comprising P+ implants in the P-well. Providing at least two fingers of a P-diode comprising P+ implants in the N-well. Surrounding each of the at least two fingers of the P-diode with an associated guard ring comprising N+ implants in the N-well.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIG. 1 illustrates a schematic block diagram of an electrostatic discharge (ESD) protection circuit for an input-output of an integrated circuit.

FIG. 2 illustrates a representative layout top view of a P-diode and an N-diode in a P-type Si wafer.

FIG. 3 illustrates a representative layout elevational cross-section of the P-type Si wafer showing the integrated circuit structure of the ESD protection comprising the P-diode and the N-diode of FIG. 2 along with N+/NWELL and P+/PWELL rings around them.

FIG. 4 illustrates a prior art representative layout top view of an N-diode having two N+ junction active fingers with one shared segment of the P+/PWELL guard rings for providing an ESD discharge path.

FIG. 5 illustrates a prior art representative layout top view of ESD discharge current paths for the two N+ junction active fingers with one shared segment of the P+/PWELL guard rings as shown in FIG. 4.

FIG. 6 illustrates a representative layout top view of ESD discharge current paths for two N+ junction active fingers with individual P+/PWELL guard rings for providing separate ESD discharge paths, according to an example.

FIG. 7 illustrates a representative layout top view of metallization for two-fingers of an N-diode, according to an example.

FIG. 8 illustrates a representative layout elevational cross-section of a P-type Si wafer showing the integrated circuit structure of a P-diode with two-fingers and an N-diode with two-fingers, each finger of the P and N diodes have a separate guard ring, according to an example.

FIG. 9A illustrates a representative layout top view of an integrated circuit structure for a vertically configured P-diode with two-fingers and an N-diode with two-fingers having separate guard rings around each finger as shown in FIG. 8, according to an example.

FIG. 9B illustrates a representative layout isometric view of the integrated circuit structure for a vertically configured P-diode with two-fingers and an N-diode with two-fingers having separate guard rings around each finger as shown in FIG. 9A, according to an example.

FIG. 10A illustrates a representative layout top view of an integrated circuit structure for a horizontally (side-by-side) configured P-diode with two-fingers and an N-diode with two-fingers having separate guard rings around each finger as shown in FIG. 8, according to another example.

FIG. 10B illustrates a representative layout isometric view of the integrated circuit structure for a horizontally (side-by-side) configured P-diode with two-fingers and an N-diode with two-fingers having separate guard rings around each finger as shown in FIG. 8, according to another example.

FIG. 11 illustrates voltage and current graphs of two active diode fingers with separate guard rings, and two active diode fingers with two guard rings having a shared ring segment, according to an example.

FIG. 12 illustrates a table of parameters comparing a prior art ESD device having two active fingers of a diode with two guard rings having a shared ring segment between the fingers, and an ESD device having two active fingers of a diode with two separate guard rings, according to the teachings of this disclosure.

To facilitate understanding, identical reference numerals have been used, where possible, to designate identical elements that are common to the figures, and a lower-case letter added where the elements are substantially the same. It is contemplated that elements of one embodiment may be beneficially incorporated in other embodiments.

### DETAILED DESCRIPTION

Electrostatic Discharge (ESD) is an exchange of charge between two objects, it occurs when contact is established and the dielectric breakdown of the material between the two objects is exceeded. ESD protection circuits provide an energy dissipation path between any combinations of two pins of an integrated circuit (IC).

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different lower-case letter suffix.

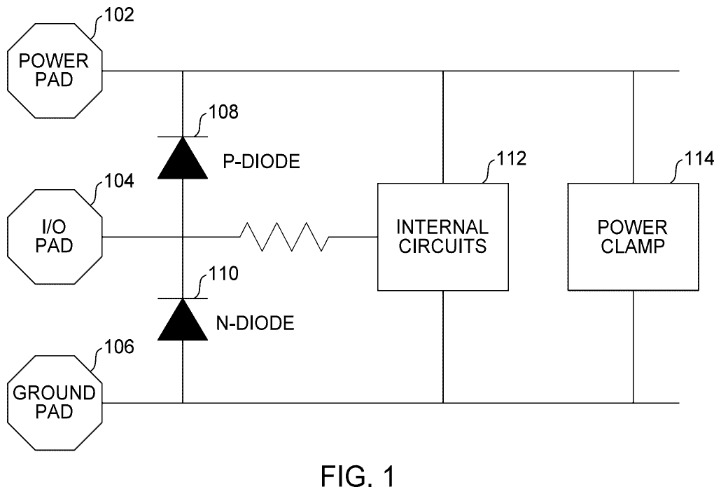

Referring now to FIG. 1, depicted is a schematic block diagram of an electrostatic discharge (ESD) protection circuit for an input-output of an integrated circuit. Dual-diode ESD protection in combination with a resistor-capacitor (RC) trigger clamp between power and ground (VDD and VSS, respectively) is the most widely used ESD protection concept.

There are four current discharge paths between I/O PAD 104, Power PAD 102 and Ground PAD 106 as follows: For a positive pulse from the I/O PAD 104 with respect to the Power PAD 102, the current flows through the P-diode 108 to the Power PAD 102. For a negative pulse from the I/O PAD 104 with respect to the Power PAD 102, the current enters a power net, goes through the Power Clamp 114, and then flows through the N-diode 110. For a positive pulse from the I/O PAD 104 with respect to the Ground PAD 106, the current goes through the P-diode 108, along a supply metal bus, through the Power Clamp 114 and to the Ground PAD 106. For a negative pulse from I/O PAD 104 with respect to the Ground PAD 106, the current flows through the N-diode 110 and out the I/O PAD 104. These discharge paths provide excellent ESD performance in protecting integrated circuit input-output (I/O) pins (electrical connections on the integrated circuit (IC) package to internal IC circuits).

One problem exists when increasing performance of ESD protection on high-speed interfaces that adds parasitic capacitances and thereby degrades signal integrity/performance during signal transmission operations. Another problem is when capacitive loading is reduced on high-speed interfaces the ESD protection is lowered, for example, by reducing diode junction active areas (to improve the signal integrity/preference during mission mode operation) which may increase the risk of ESD protection failure.

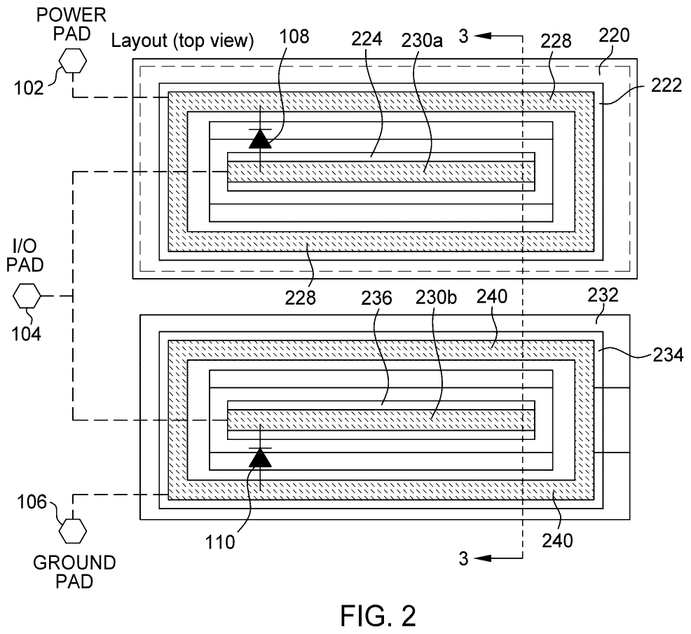

Referring to FIG. 2, depicted is a representative layout top view of a P-diode and an N-diode in a P-type Si wafer. A P-diode 108 is typically used as the discharge path between a signal pad (e.g., I/O PAD 104) and V_{DD} in a diode-based ESD protection scheme with P-type Si wafers. An N-diode 110 is typically used as the discharge path between V_{SS} and the signal pad (e.g., I/O PAD 104) in a diode-based ESD protection scheme with P-type Si wafers. However, this type of ESD protection for high-speed data input-output interfaces degrades the data signal integrity, primarily due to the capacitive loading of the ESD protection on a signal net. The I/O pad 104 may be for a signal input, a signal output, or a signal input and output.

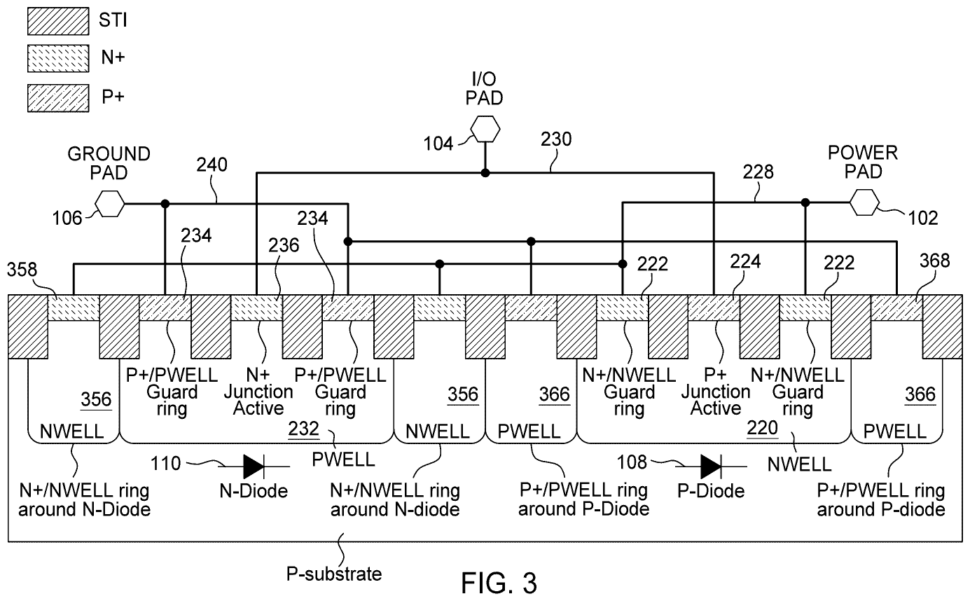

Referring to FIG. 3, depicted is a representative layout elevational cross-section of the P-type Si wafer showing the integrated circuit structure of the ESD protection comprising the P-diode and the N-diode of FIG. 2. The elevational view is of section 3-3 of FIG. 2. The N-diode 110 is formed in a P-well 232 in which P+ implant 234 forms a P+/P-well guard ring, and an N+ implant 236 forms an active N+ junction, with shallow trench isolation (STI) therebetween. The P-diode 108 is formed in an N-well 220 in which N+ implant 222 forms a N+/NWELL guard ring, and a P+ implant 224 forms an active P+ junction, with shallow trench isolation (STI) therebetween. The P+ implant 234 forms the anode of the N-diode 110 and is coupled to the ground pad 106. The N+ implant 236 forms the cathode of the N-diode 110 and is coupled to the I/O pad 104. The N+ implant 222 forms the cathode of the P-diode 108 and is coupled to the power pad 102. P+ implant 224 forms the anode of the P-diode 108 and is coupled to the I/O pad 104. An N-well ring 356 surrounds the P-well 232 of the N-diode 110. A P-well ring 366 surrounds the N-well 220 of the P-diode 108.

Referring back to FIG. 2, metallization 230a couples the P+ junction implant 224 to the I/O pad 104, and metallization 230b couples the N+ junction implant 236 to the I/O pad 104. Metallization 228 couples the N+ implant 222 (N+/N-well guard ring) to the power pad 102. Metallization 240 couples the P+ implant 234 (P+/P well guard ring) to the ground pad 106.

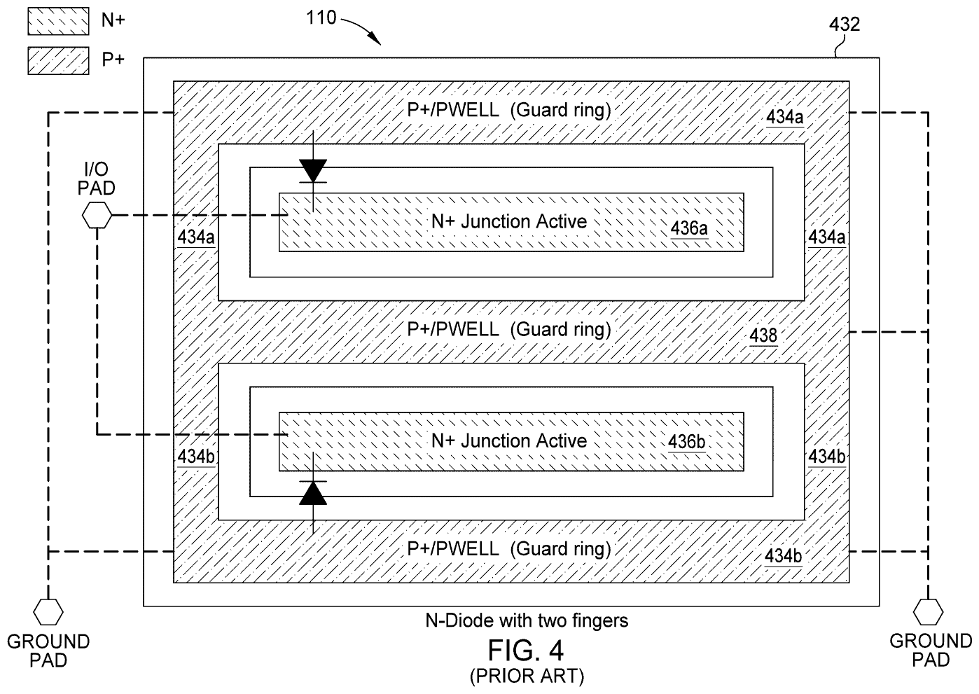

Referring to FIG. 4, depicted is a prior art representative layout top view of an N-diode having two N+ junction active fingers with one shared segment of the P+/PWELL guard rings for providing an ESD discharge path. The two fingers 436a and 436b of the N-diode 110 are formed in a shared P-well (e.g., P-well 232 of FIG. 3). The finger 436a comprises an N+ junction (active) and a P+/P-well guard ring having P+ segments 434a and 438. The finger 436b comprises an N+ junction (active) and a P+/P-well guard ring having P+ segments 434b and 438. P+ segment 438 is shared between both fingers 436a and 436b of the N-diode 110.

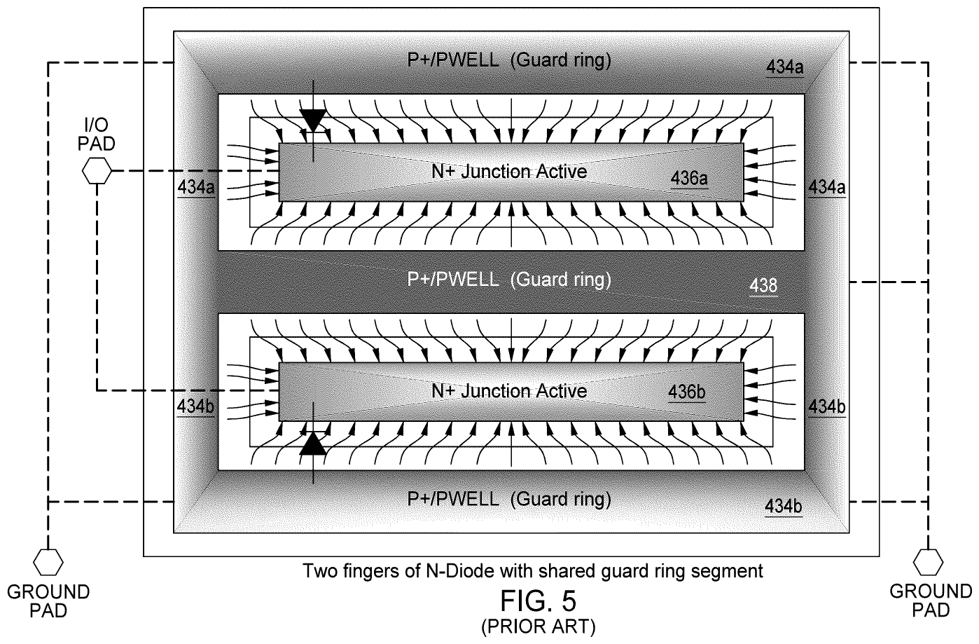

Referring to FIG. 5, depicted is a prior art representative layout top view of ESD discharge current paths for the two N+ junction active fingers with one shared segment of the P+/PWELL guard rings as shown in FIG. 4. The structure shown in FIG. 5 represents two N+ junction active fingers 436a and 436b with a shared P+ segment 438 used for two P+/PWELL guard rings that provide discharge paths for an ESD event from the two N+ junction active fingers 436a and 436b. During the ESD event, current will discharge from the two N+ junction active fingers 436a and 436b to the P+/PWELL guard ring segments 434a, 434b and 438, with segment 438 being shared by both guard rings. Current crowding occurs on the middle guard ring segment 438 since it is shared between the N+ junction active fingers 436a and 436b. Also, when two or more (e.g., N+ Junction) fingers are coupled in proximity, they will heat each other during an ESD event.

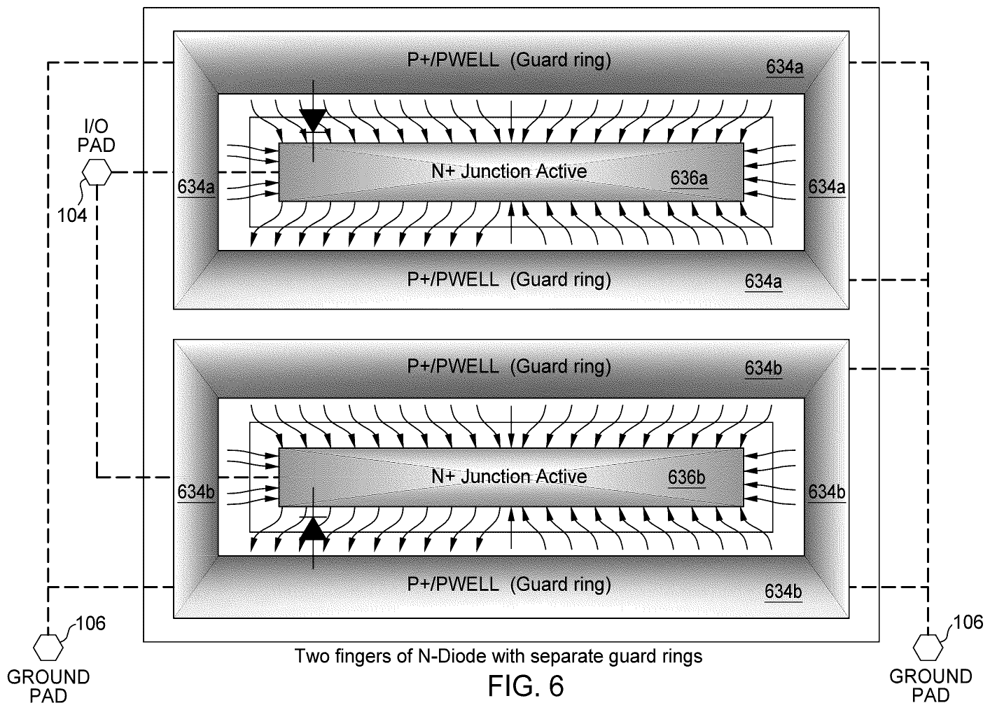

Referring to FIG. 6, depicted is a representative layout top view of ESD discharge current paths for two fingers of an N-diode with individual P+/PWELL guard rings for providing separate ESD discharge paths, according to an example. The structure shown in FIG. 6 represents two N+ junction active fingers 636a and 636b with separate P+/PWELL guard rings 634a and 634b, respectively, that provide discharge paths for an ESD event from the two N+ junction active fingers 636a and 636b of the N-diode 110. During an ESD event, current will discharge from the two N+ junction active fingers 636a and 636b to the two separate P+/PWELL guard rings, one comprising 634a for the N+ junction finger 636a and the other comprising 634b for the N+ junction finger 636b. No current crowding occurs on either of the P+/PWELL guard rings (634a, 634b) so that the current from the ESD event is evenly and equally distributed from the two N+ junction fingers 636a and 636b.

The configuration shown in FIG. 6 provides for an increase in the area of the guard rings, which decreases the current density and heat generated for the same ESD event current. The self-heating between the two N+ Junction fingers 636a and 636b is also reduced (because of more distance). Overall, the ESD performance (in terms of thermal breakdown current and on-resistance) is improved. This also allows adding extra metallization on the adjacent segments of the P+/PWELL guard rings (634a, 634b) to reduce resistance from the P-diode 108 and N-diode 110 to the power clamp 114. A representative layout for an N-diode two-finger configuration is shown in FIG. 6 but a similar representative layout for a P-diode two-finger configuration using the appropriate N+ and P+ implants are contemplated and included in this disclosure. Increased area guard rings have greater current carrying capacity and therefor allow for smaller ESD diodes needed for an ESD handling requirement. Using smaller ESD diodes provides for lower capacitance loading on the I/O pad 104.

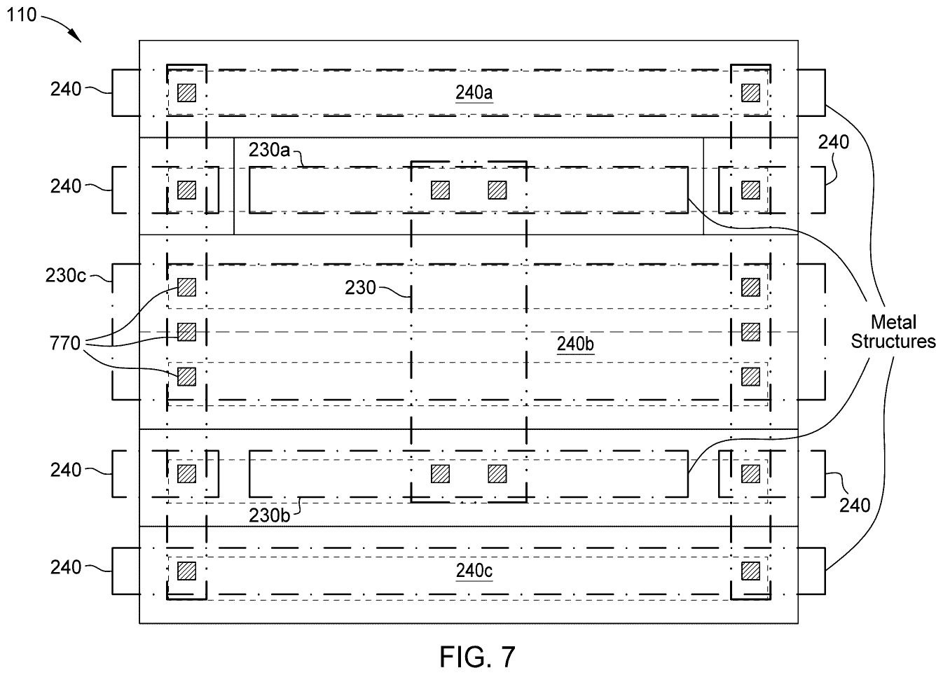

Referring to FIG. 7, depicted is a representative layout top view of metallization for two fingers of an N-diode, according to an example. The metallization element references are for fingers 636a and 636b of the N-diode 110, but this metallization representative layout is also applicable for the two fingers of the P-diode 108. The metallization 240 is adapted for coupling to a ground pad 106, and the metallization 230 is adapted for coupling to an I/O pad 104. The metallization 240b may be wider than the metallization 240a and 240c because it is coupled to the portions of the guard rings adjacent to each other (e.g., 634a and 634b of FIG. 6). This widened and optionally thicker metal has a reduced resistance and can better dissipate heat from the adjacent segments of the guard rings. Metallization 230 may also be wider (and thicker) for lower resistance and better heat dissipation. Metallization may be insulated from the N+ and P+ implants and from crossovers of the different metallization circuits, e.g., metallization 230 and 240 with oxide diffusion (OD) layers. Connections from the various metallization used for V_{SS} (240 to ground pad 106), V_{DD} (228 to power pad 102) and I/O (230 to I/O pad 104) to the N+ and P+ implants are with metal filled vias 770 through the OD layers. Metals used for the metallization may be, for example but are not limited to, copper and aluminum.

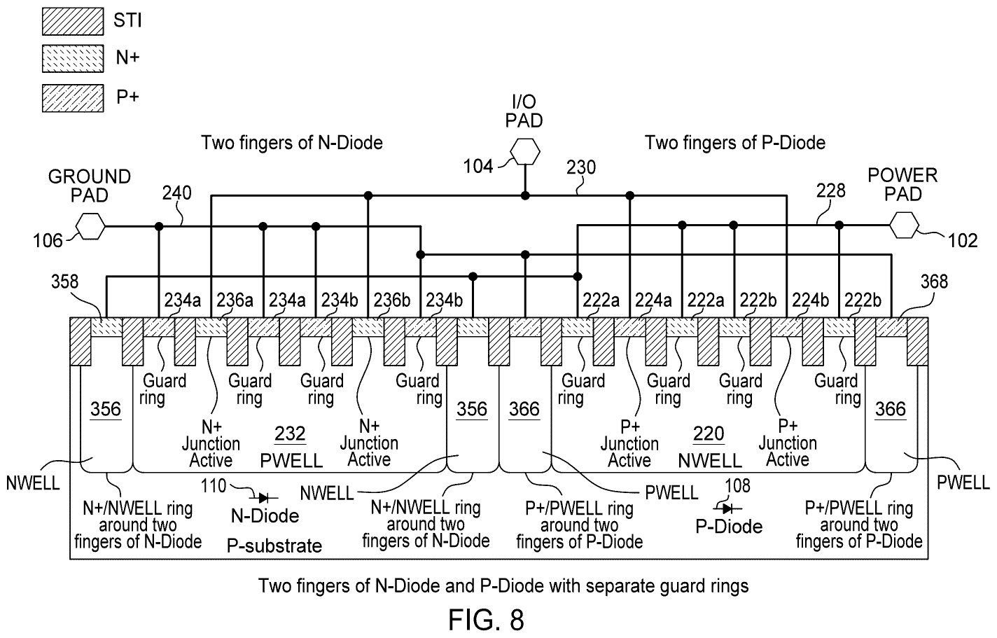

Referring to FIG. 8, depicted is a representative layout elevational cross-section of a P-type Si wafer showing the integrated circuit structure of a P-diode with two fingers and an N-diode with two fingers, each finger of the P and N diodes have a separate guard ring, one guard ring for each finger, according to an example. The two fingers (236a and 236b) of the N-diode 110 are formed in a P-well 232 in which P+ implants 234a and 234b form two separate P+/P-well guard rings, and two N+ implants 236a and 236b form the active N+ junction fingers, with shallow trench isolation (STI) therebetween. Two fingers (224a and 224b) of the P-diode 108 are formed in an N-well 220 in which N+ implants 222a and 222b form two separate N+/N-well guard rings, and two P+ implants 224a and 224b form active P+ junction fingers, with shallow trench isolation (STI) therebetween. The P+ implants 234a and 234b form the anodes of the N-diode 110 and are coupled to the ground pad 106. The N+ implants 236a and 236b form the cathode of the N-diode 110, and are coupled to the I/O pad 104. The N+ implants 222a and 222b form the cathode of the P-diode 108, and are coupled to the power pad 102. The P+ implants 224a and 224b form the anode of the P-diode 108 and are coupled to the I/O pad 104. An N-well ring 356 surrounds the P-well 232 of the N-diode 110. A P-well ring 366 surrounds the N-well 220 of the P-diode 108.

Similarly, four, six, eight finger (or more) N-diodes with a separate guard ring for each diode finger may be fabricated in a single P-well 232; as can four, six, eight fingers (or more) of a P-diode with a separate guard ring for each diode finger may be fabricated in a single N-well 220. Also, a single diode finger may be added to make an odd number of diode fingers, each with a separate guard ring, in the single P-well 232, and the single N-well 220 for a plurality of fingers of the P-diode. As described above, an N-well ring 356 surrounds the P-well 232 of the plurality of fingers of the N-diode. A P-well ring 366 surrounds the N-well 220 of the plurality of fingers of the P-diode. The number of ESD diode fingers required is determined by the ESD current withstand requirements of the integrated circuit design.

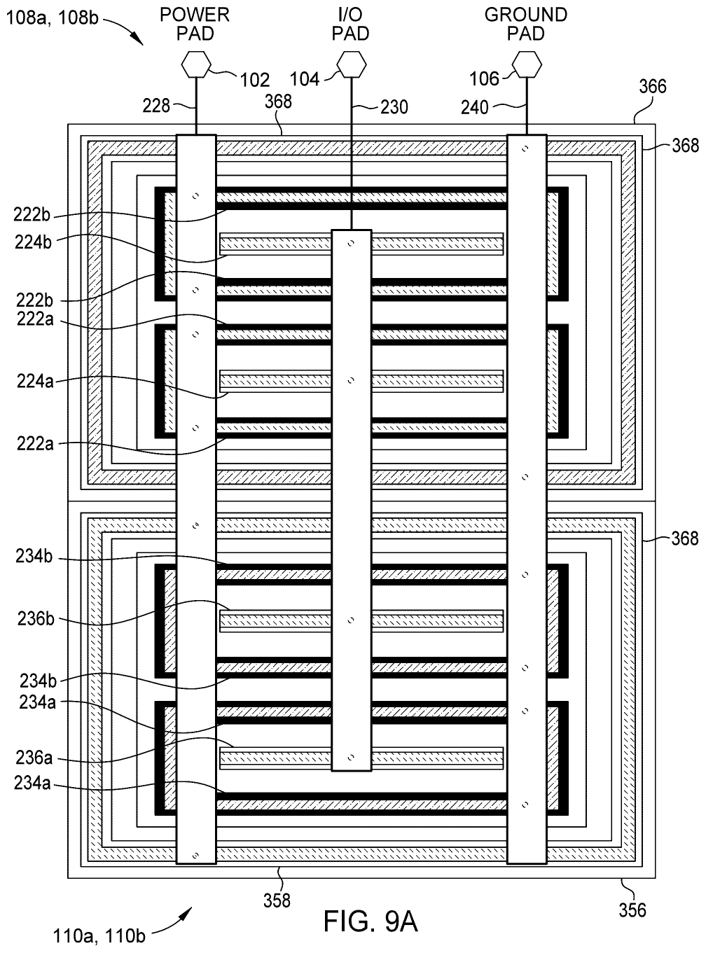

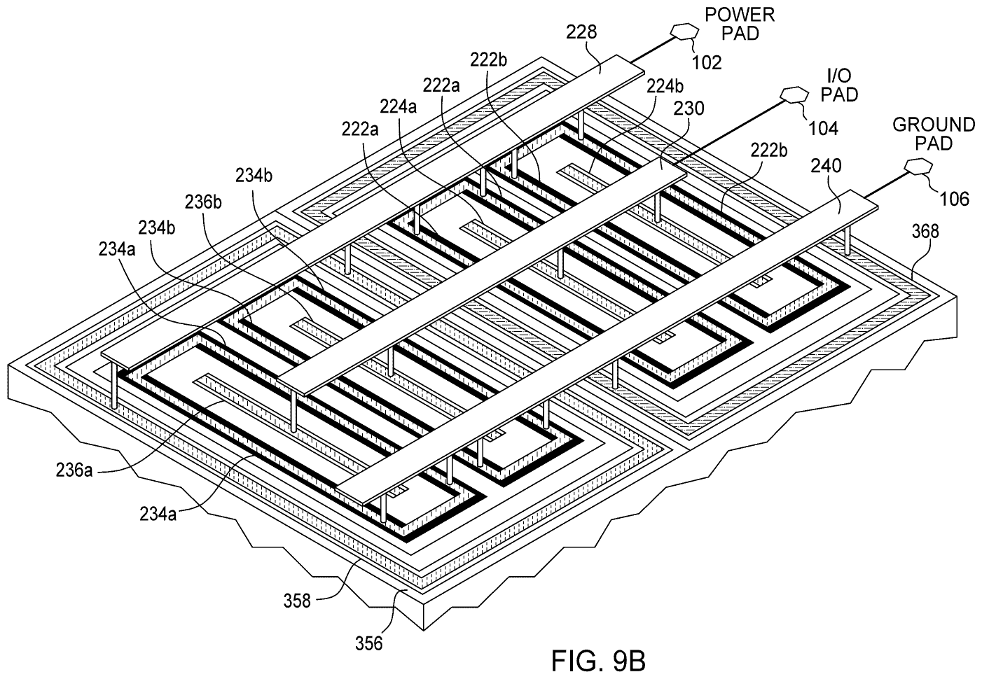

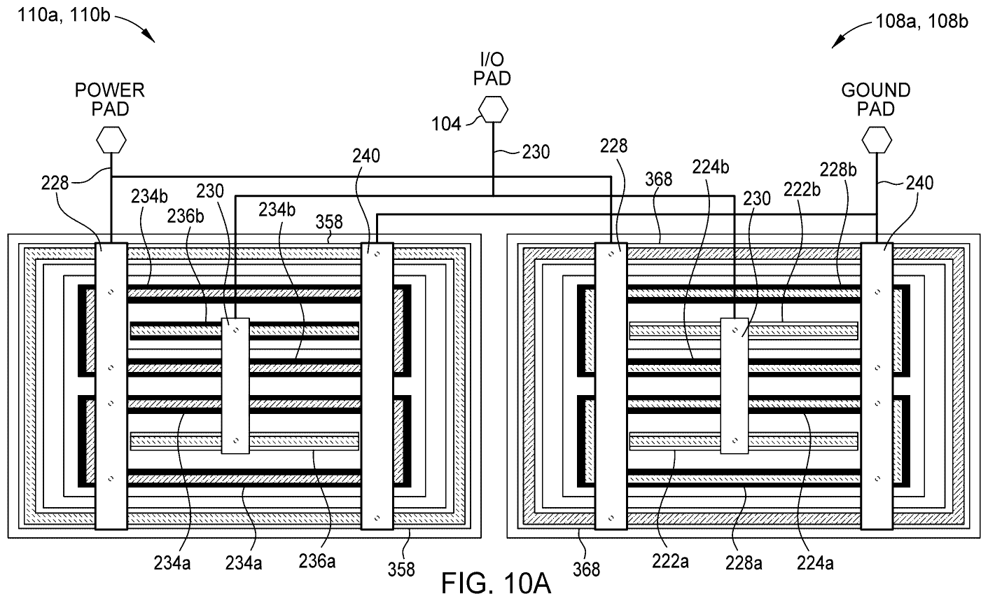

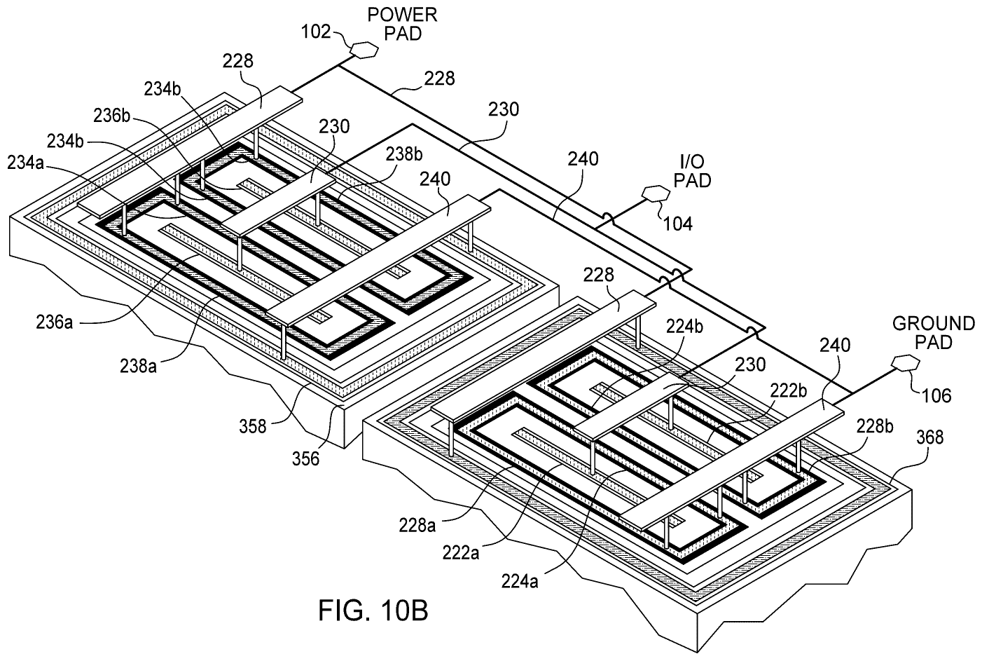

FIGS. 9A and 10A illustrate representative layout top views of integrated circuit structures for a P-diode having two-fingers and an N-diode having two-fingers, each finger having a separate guard ring as shown in FIG. 8, according to examples. FIGS. 9B and 10B illustrate representative layout isometric views of the integrated circuit structures shown in FIGS. 9A and 10A, according to examples. The P-diode 108 is fabricated in the N-well 220 and the N-diode 110 is fabricated in the P-well 232, both may be configured vertically as shown in FIGS. 9A and 9B or horizontally as shown in FIGS. 10A and 10B, on a semiconductor integrated circuit wafer (not shown). Also, a plurality of these structures may be fabricated on the integrated circuit wafer (die) depending upon the ESD current withstand requirements of the integrated circuit design.

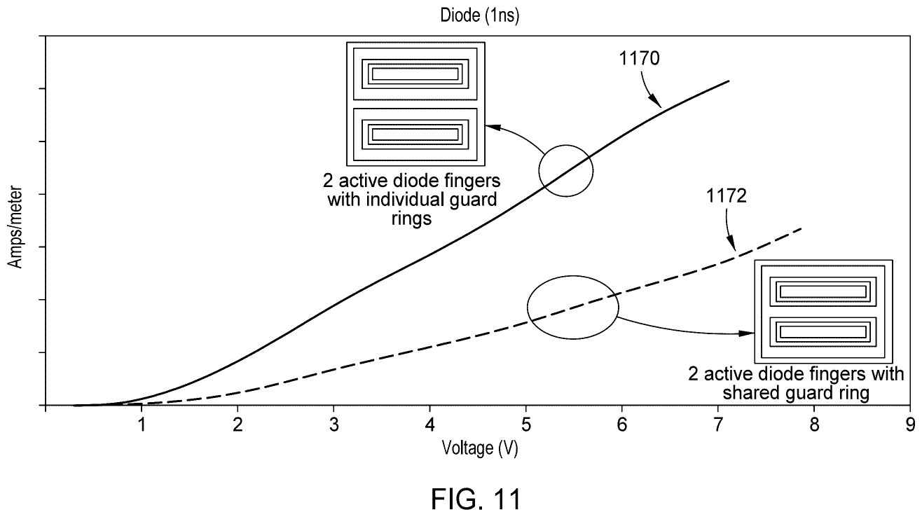

FIG. 11 illustrates voltage and current graphs of two active diode fingers with separate guard rings, and two active diode fingers with two guard rings having a shared ring segment, according to an example. As shown in the graphs of FIG. 11, the two active diode fingers with separate guard rings have about twice the failure current withstand as the two active diode fingers with two guard rings having a shared ring segment. Using separate guard rings is a significant improvement that provides more robust ESD protection. A significant advantage in using the active diode fingers with separate guard rings is that fewer diode fingers are required for a given design, which results in less capacitance loading on the I/O port of the integrated circuit that the ESD circuit is protecting. Another advantage is that metals that are parallel with the diode fingers and connect to the guard rings surrounding the diode fingers and connect to groups or power (for example, 240a for an N-diode) can be moved away from the diode finger metallization parallel to the diode fingers (230a for example) to reduce the capacitance of the diode without degrading the ESD performance.

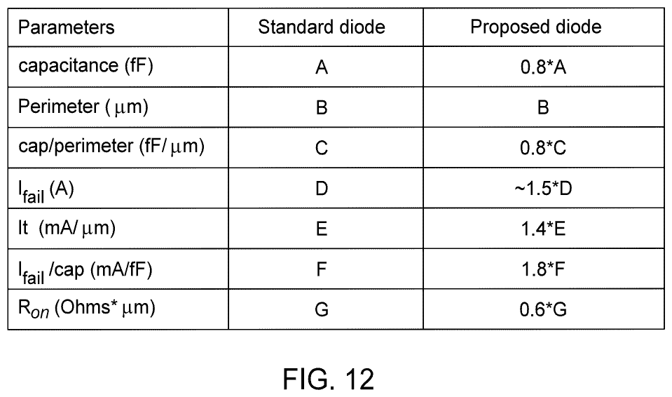

FIG. 12 illustrates a table of parameters comparing a prior art ESD device having two active diode fingers with two guard rings having a shared ring segment, and an ESD device having two active diode fingers with separate guard rings, according to the teachings of this disclosure. Further to the improved ESD current handling capabilities of the active diode fingers with separate guard rings, as shown in the graph of FIG. 11. FIG. 12 tabulates the advantages of the embodiments disclosed herein over the prior art ESD circuits. These advantages are for example but not limited to:

### Area Reduction:

The example ESD diode disclosed herein has about 1.5 to 2 times the It (failure current) and about 0.5 to 0.6 times the on-resistance of a prior art ESD diode. Therefore, for a given design target, the perimeter of the example ESD diode is about 0.5-0.6 times that of a prior art ESD diode.

### Parasitic Capacitance Reduction:

Because the metal is optimized for capacitance, the capacitance per diode perimeter is lower. As shown in the table of FIG. 12, the prior art ESD diode capacitance is about 1*C femtofarads per micrometer, whereas the example ESD diode has a capacitance of about 0.8*C femtofarads per micrometer, a 20 percent reduction in capacitance.

Hence the example ESD diode has higher ESD performance in a smaller area as compared to the prior art ESD performance. The example ESD diode structure may be used in any diode based ESD protection design, and especially for high-speed interfaces benefiting from lower node (net) capacitance. Also, with the higher ESD current withstand, less ESD diode devices are required, thus minimizing the capacitive loading on high-speed data circuits.

As will be appreciated by one skilled in the art and having the benefit of this disclosure, the embodiments disclosed herein may be embodied as a system, method, apparatus, or computer programmed product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

While the foregoing is directed to embodiments of the present invention, other and further embodiments of the invention may be devised without departing from the basic scope thereof, and the scope thereof is determined by the claims that follow.

What is claimed is:

1. An apparatus for protection of integrated circuit inputs and outputs from electrostatic discharge (ESD), comprising:
an integrated circuit (IC) substrate;
a P-well in the IC substrate;
an N-well in the IC substrate;
an N-well ring around the P-well and in the IC substrate;
a P-well ring around the N-well and in the IC substrate;
at least two fingers of an N-diode comprising N+ implants in the P-well;
at least two guard rings comprising P+ implants in the P-well, wherein each guard ring surrounds an associated finger of the N-diode;
at least two fingers of a P-diode comprising P+ implants in the N-well; and
at least two guard rings comprising N+ implants in the N-well, wherein each guard ring surrounds an associated finger of the P-diode.

2. The apparatus according to claim 1, wherein the IC substrate is a P-substrate.

3. The apparatus according to claim 1, further comprising shallow trench isolation (STI) between the P+ and N+ implants.

4. The apparatus according to claim 1, wherein the P+ implants in the P-well ring are adapted for coupling to an IC ground pad.

5. The apparatus according to claim 4, wherein the P+ implants in the P-well are adapted for coupling to the IC ground pad.

6. The apparatus according to claim 1, wherein the N+ implants in the N-well ring are adapted for coupling to an IC power pad.

7. The apparatus according to claim 6, wherein the N+ implants in the N-well are adapted for coupling to the IC power pad.

8. The apparatus according to claim 1, wherein the N+ implants in the P-well are adapted for coupling to an IC signal pad.

9. The apparatus according to claim 8, wherein the P+ implants in the P-well are adapted for coupling to the IC signal pad.

10. The apparatus according to claim 9, wherein the IC signal pad is an input signal pad.

11. The apparatus according to claim 9, wherein the IC signal pad is an output signal pad.

12. The apparatus according to claim 9, wherein the IC signal pad is an input/output signal pad.

13. An integrated circuit (IC) having electrostatic discharge (ESD) protection for signal inputs and signal outputs of the IC, the IC comprising:
an integrated circuit (IC) substrate having electronic circuits with signal inputs and outputs; and
at least one ESD protection circuit for each signal input and each signal output of the electronic circuits;
wherein each one of the at least one ESD protection circuits comprises:
a P-well in the IC substrate;
an N-well in the IC substrate;
an N-well ring around the P-well and in the IC substrate;
a P-well ring around the N-well and in the IC substrate;
at least two fingers of an N-diode comprising N+ implants in the P-well;
at least two guard rings comprising P+ implants in the P-well, wherein each guard ring surrounds an associated finger of the N-diode;
at least two fingers of a P-diode comprising P+ implants in the N-well; and
at least two guard rings comprising N+ implants in the N-well, wherein each guard ring surrounds an associated finger of the P-diode.

14. The IC according to claim 13, wherein the P+ implants in the P-well ring and the P+ implants in the P-well are coupled to an IC ground bus.

15. The IC according to claim 13, wherein the N+ implants in the N-well ring and the N+ implants in the N-well are coupled to an IC power bus.

16. The IC according to claim 13, wherein the N+ implants of the at least two fingers of the N-diode and the P+ implants of the at least two fingers of the P-diode are coupled to an IC signal circuit.

17. A method for forming an electrostatic discharge (ESD) protection structure for signal inputs and signal outputs of an integrated circuit (IC), comprising:
forming a P-well in an IC substrate;
forming an N-well in the IC substrate;
forming the P-well with an N-well ring in the IC substrate;
forming the N-well with a P-well ring in the IC substrate;
forming at least two fingers of an N-diode comprising N+ implants in the P-well;
surrounding each of the at least two fingers with an associated guard ring comprising P+ implants in the P-well;
forming at least two fingers of a P-diode comprising P+ implants in the N-well; and
surrounding each of the at least two fingers of the P-diode with an associated guard ring comprising N+ implants in the N-well.

18. The method according to claim 17, further comprising coupling a ground bus of the IC to the P+ implants in the P-well ring and the P+ implants in the P-well.

19. The method according to claim 17, further comprising coupling a power bus of the IC to the N+ implants in the N-well ring and the N+ implants in the N-well.

20. The method according to claim 17, further comprising coupling a signal circuit of the IC to the N+ implants of the at least two fingers of the N-diode and the P+ implants of the at least two fingers of the P-diode.
